(19) United States
(12) Patent Application Publication
(10) Pub. No.: US 2016/0192085 A1
(43) Pub. Date: Jun. 30, 2016

(54) MEMS MICROPHONE PACKAGE USING LEAD FRAME

(71) Applicant: IMAGIS CO., LTD., Gyeonggi-do (KR)

(72) Inventors: Jung Kyu LEE, Gyeonggi-do (KR); Gyun Tae KIM, Incheon (KR); Jong Seo KIM, Incheon (KR)

(21) Appl. No.: 14/942,002

(22) Filed: Nov. 16, 2015

(30) Foreign Application Priority Data
Dec. 30, 2014 (KR) 10-2014-0194446

(51) Int. Cl. H04R 19/04; H04R 1/04; B81B 7/00

(52) U.S. Cl. CPC H04R 19/04; B81B 7/007; H04R 1/04; B81B 2201/0257; B81B 3/0018

(57) ABSTRACT

The present disclosure discloses an MEMS microphone package. The MEMS microphone package in accordance with the present disclosure comprises a lead frame; an integrated MEMS chip mounted on the lead frame, having a vibration unit comprising a diaphragm and a backplate spaced each other with an air gap between them and a signal processing unit for amplifying electric signals generated in the vibration unit formed on a single silicon substrate; and an electric connection means for connecting the lead frame to the integrated MEMS chip.

### CROSS-REFERENCE TO RELATED PATENT APPLICATION

This application claims the benefit of Korean Patent Application No. 10-2014-0194446, filed on 30 Dec. 2014 in the Korean Intellectual Property Office. The entire disclosure of the application identified in this paragraph is incorporated herein by reference.

### FIELD

The present disclosure relates to a MEMS microphone package, and more particularly to a MEMS microphone package comprising an integrated MEMS chip integrating a vibration unit and a signal processing unit into one chip and being mounted on a lead frame.

### BACKGROUND

There are many different types of microphones depending on their materials or operation principle, as a device for converting acoustic signals to electric signals. In general, they are classified into carbon microphones, crystal microphones, and magnetic microphones depending on their materials, and into dynamic microphones using induced electromotive forces by magnetic fields and condenser microphones using capacitance changes resulting from vibrations of diaphragms depending on their operation principle.

Among them, very small condenser microphones, for example, ECMs (Electret Condenser Microphones) and MEMS (Micro Electro Mechanical System) microphones, are generally used for portable or small electronic devices, for example, computers, mobile communication terminals, MP3 recorders, cassette recorders, camcorders and headsets.

An ECM has a semi-permanently polarized electret layer formed on the diaphragm or backplate thereof, and does not need a DC bias power supply. Although the process of manufacturing the ECM is simple, it is known that the following issues are involved.

First, since the electret layer is very vulnerable to heat, the reflow process at high temperature is not applicable to mounting a finished product on the substrate of an electronic device, and soldering is a solution just applicable for the purpose. Therefore, it is a barrier to enhancing productivity.

Second, since it is difficult to fill the electret layer with charges in a uniform distribution, sensitivity greatly varies product by product, and the charges filled in the electret layer flow out in a highly humid environment to result in non-uniform sensitivity.

On the other hand, a MEMS microphone is manufactured by forming microphone components, for example, a diaphragm and a backplate on a silicon substrate through ultra precision process by applying semiconductor manufacturing techniques. Since electret materials vulnerable to heat are not used, it is allowed to mount the MEMS microphone on a main substrate of portable phones through the high-temperature reflow process, and it is an advantage that there is no issue of great sensitivity deviations among products. This results in significantly growing demands for MEMS microphones.

FIG. 1 is a cross sectional view showing a schematic configuration of a conventional MEMS microphone package 20. As shown in FIG. 1, the MEMS microphone package 20 includes a PCB (Printed Circuit Board) 21 with an external connection terminal 22 thereunder, a MEMS element 30 and an amplifying element 25 mounted on the upper surface of the PCB 21, a bonding wire 26 for connecting the MEMS element 30 to the amplifying element 25 and a metallic case 23 coupled to the PCB 21 and having a sound hole 24 while enclosing the MEMS element 30 and the amplifying element 25.

The MEMS element 30 includes a diaphragm 33 formed on top of a silicon substrate 31, a backplate 34 located on top of the diaphragm 33 with an air gap between them and formed with a plurality of sound holes 35, and a back-chamber 32 formed to expose the diaphragm 33 toward the lower side of the silicon substrate 31.

The amplifying element 25 amplifies electric signals generated in the MEMS element 30 by means of sound pressure, and is usually composed of an ASIC (Application-Specific Integrated Circuit). The signal amplified by the amplifying element 25 is sent to the main substrate of an electronic device, for example, a mobile phone, through the external connection terminal 22.

By the way, a conventional MEMS microphone package 20 involves the following issues.

First, the process of manufacturing a package is complex because it is essential to produce the MEMS element 30 and the amplifying element 25, respectively, and mount each of them on the PCB 21 through a different mounting process.

Second, since it is essential to use a PCB 21 of sufficient size for mounting the MEMS element 30 and the amplifying element 25 on the PCB 21, respectively, reducing the package size is limited and it is thereby not easy to respond to the demand for a compact package.

### RELEVANT ART

Patent 1: Korea Patent Registration No. 10-0925558 (published on Nov. 5, 2009)

### SUMMARY

In view of the above, the present disclosure aims to further simplify the process of manufacturing MEMS microphone packages, and thereby enhance productivity. In addition, the present disclosure aims to further compact the size of a MEMS microphone package.

To achieve aforementioned aims, in accordance with an embodiment of the present disclosure, there is provided a MEMS microphone package including a lead frame; an integrated MEMS chip mounted on the lead frame, having a vibration unit comprising a diaphragm and a backplate spaced each other with an air gap between them and a signal processing unit for amplifying electric signals generated in the vibration unit, the vibrating unit and the signal processing unit being formed on a single silicon substrate, the vibrating unit being formed on a first area of the silicon substrate through MEMS process and the signal processing unit being formed on a second area located in the lateral direction of the first area on the silicon substrate; and an electric connection means for connecting the lead frame to the integrated MEMS chip.

In the MEMS microphone package in accordance with an embodiment of the present disclosure, the vibrating unit is formed on a first area of the single silicon substrate and the signal processing unit is formed on a second area enclosing the first area.

In addition, the MEMS microphone package in accordance with an embodiment of the present disclosure includes a molded portion enclosing the electric connection means, the integrated MEMS chip and the lead frame, and the molded portion encloses the outer area of a sound diffusion chamber formed on one side of the integrated MEMS chip. In this case, a metallic shielding panel covering the top of the sound diffusion chamber is coupled to the upper side of the molded portion, and the shielding panel is formed with a sound hole communicating with the sound diffusion chamber. In addition, the lead frame includes a shielding frame connected to the shielding panel through the molded portion.

In addition, in accordance with an embodiment of the present disclosure, there is provided a MEMS microphone package including a molded portion enclosing the electric connection means, the integrated MEMS chip and the lead frame, a sound diffusion chamber is formed between the lead frame and the integrated MEMS chip, and a sound hole communicating with the sound diffusion chamber is formed through the lead frame. In this case, a metallic shielding panel is coupled to the upper side of the molded portion. In addition, the lead frame includes a shielding frame connected to the shielding panel through the molded portion.

In addition, the MEMS microphone package in accordance with an embodiment of the present disclosure further includes a lateral molding wall formed along the outer area of the lead frame; and a molding cover coupled to the upper end of the lateral molding wall and formed with a sound hole. In this case, the space enclosed by the lateral molding wall and the molding cover is used as a sound diffusion chamber. In this case, a metallic shielding panel is coupled to at least one of the lateral molding wall and the molding cover.

In addition, the MEMS microphone package in accordance with an embodiment of the present disclosure further includes a lateral molding wall formed along the outer area of the lead frame, and a metallic shielding panel coupled to the upper end of the lateral molding wall and formed with a sound hole, wherein the space enclosed by the lateral molding wall and the shielding panel is used as a sound diffusion chamber. In this case, a second sound diffusion chamber is formed between the lead frame and the integrated MEMS chip, and the lead frame is formed with a sound hole communicating with the second sound diffusion chamber.

The foregoing summary is illustrative only and is not intended to be in any way limiting. In addition to the illustrative aspects, embodiments, and features described above, further aspects, embodiments, and features will become apparent by reference to the drawings and the following detailed description.

### Effect of the Invention

In accordance with the present disclosure, since the integrated MEMS chip having a vibration unit and a signal processing unit formed on a single silicon substrate is mounted on a lead frame, the process of manufacturing a package is simplified in comparison with the conventional method of manufacturing and mounting two chips, respectively, and thus significantly enhances productivity. Since just one chip is mounted on a lead frame, package size is greatly reduced in comparison with the conventional method of mounting two chips on a substrate.

### BRIEF DESCRIPTION OF THE DRAWINGS

FIG. 1 is a cross sectional view showing a schematic configuration of a conventional MEMS microphone package;

FIG. 2 is a cross sectional view showing a MEMS microphone package in accordance with a first embodiment of the present disclosure;

FIG. 3 is a schematic cross sectional view of an integrated MEMS chip in accordance with an embodiment of the present disclosure;

FIGS. 4 to 8 are cross sectional views illustrating different variants of the MEMS microphone package in accordance with the first embodiment of the present disclosure;

FIG. 9 is a cross sectional view of a MEMS microphone package in accordance with a second embodiment of the present disclosure; and

FIGS. 10 to 14 are cross sectional views illustrating different variants of the MEMS microphone package in accordance with the second embodiment of the present disclosure.

It should be understood that the appended drawings are not necessarily to scale, presenting a somewhat simplified representation of various features illustrative of the basic principles of the present disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

Hereinafter, the embodiments of the present disclosure will be described in detail with reference to the accompanying drawings.

First, although the dimensions shown in the drawings are quite different from real dimensions of a MEMS microphone package, they are just for easy description, and it should thus be noted that this does not limit the scope of the present disclosure.

### First Embodiment

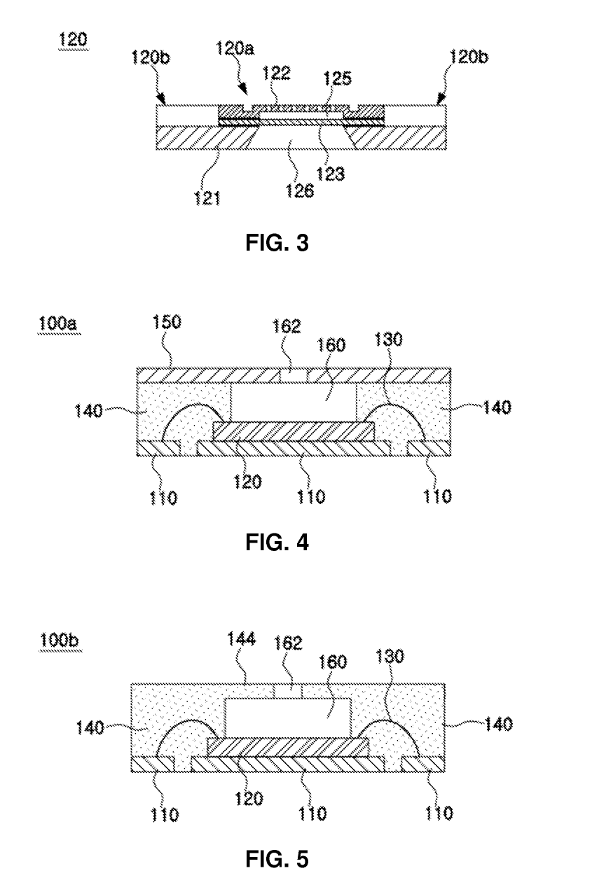

As shown in the cross sectional view of FIG. 2, the MEMS microphone package 100 in accordance with the first embodiment of the present disclosure includes a lead frame 110, an integrated MEMS chip 120 mounted on the upper side of the lead frame 110, a bonding wire 130 used for connecting the lead frame 110 electrically to the integrated MEMS chip 120, a molded portion 140 enclosing the outer area of the integrated MEMS chip 120 and the bonding wire 130, and a shielding panel 150 coupled to the upper side of the mold.

The lead frame 110 is made of a metallic material, and has a mounting surface for mounting the integrated MEMS chip 120 thereon. In addition, it includes a plurality of terminals for connecting the main substrate of an electronic device, for example, a mobile phone, and the terminals may include a lead terminal for sending electric signals generated in the integrated MEMS chip 120 and a ground terminal for grounding or shielding.

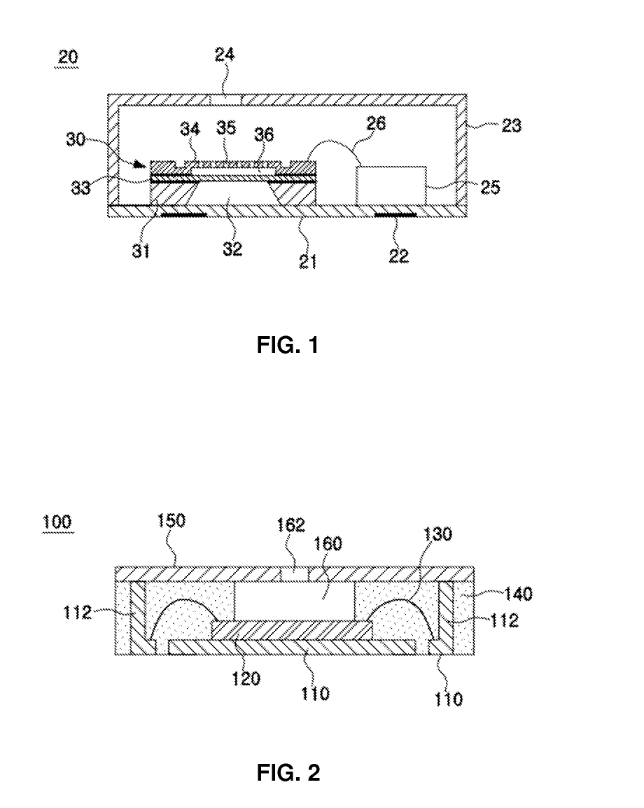

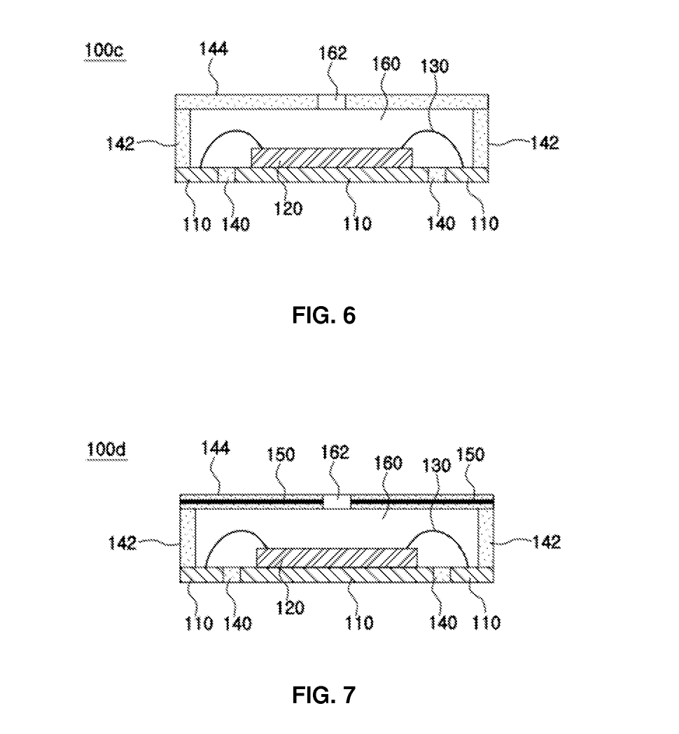

As shown in the schematic cross sectional view of FIG. 3, the integrated MEMS chip 120 is different from the conventional MEMS element 30 or the amplifying element 25 shown in FIG. 1. In the integrated MEMS chip 120, a vibration unit 120a and a signal processing unit 120b is integrated on a single silicon substrate 121 as shown FIG. 3.

That is, the integrated MEMS chip 120 used in the MEMS microphone package 100 in accordance with the first embodiment of the present disclosure includes, on the silicon substrate 121, a vibration unit 120a including a diaphragm 123 and a backplate 122 facing each other with an air gap 125 between them, and a back-chamber 126 formed under the diaphragm 123. In addition, the integrated MEMS chip 120 includes a signal processing unit 120b formed in the area enclosing the vibration unit 120a and for amplifying electric signals generated in the vibration unit 120a on the same silicon substrate 121. This also applies to the integrated MEMS chip 120 used in a package 200 in accordance with a second embodiment described further below.

As described above, using the integrated MEMS chip 120 contributes to significantly reducing the package size and reducing the number of mounting process to its half to result in significantly enhancing the packaging process productivity in comparison with the case of conventional separate installation of an MEMS element and an amplifying element on a PCB.

Meanwhile, the method or sequence of manufacturing the integrated MEMS chip 120 is not limited to a specific method or sequence. As an example, the vibration unit 120a may be formed by applying conventional MEMS process on a given area of the silicon substrate 21 and then the signal processing unit 120b may be formed by applying a conventional ASIC manufacturing process on the outer area of the vibration unit 120a while the formed vibration unit 120a is shielded.

As another example, the signal processing unit 120b may be formed by applying conventional ASIC manufacturing process in the area enclosing the vibration unit 120a on the silicon substrate 21 and then the vibration unit 120a may be formed by applying conventional MEMS process on the inner side of the signal processing unit 120b while the formed signal processing unit 120b is shielded.

As still another example, continuous process steps may be applied to simultaneously forming the vibration unit 120a and the signal processing unit 120b.

A specific shape of the aforementioned integrated MEMS chip 120 is not limited to the examples shown in the drawings. For example, although the backplate 122 is shown located above the diaphragm 123 in FIG. 3, the diaphragm 123 may be formed above the backplate 122. In addition, although the back-chamber 126 is formed under the diaphragm 123 in FIG. 3, the back-chamber 126 may be formed on top of the backplate 122 depending on the location of sound holes. In addition, although a plurality of through-holes are formed just through the backplate 122 in FIG. 3, the through-holes may be formed even through the diaphragm 123.

In addition, although the signal processing unit 120b is formed along the outer edge of the vibration unit 120a in FIG. 3, the signal processing unit 120b may be formed just on one side of the vibration unit 120a. In addition, the shapes of the backplate 122, the diaphragm 123, and the back-chamber 126 are not limited to those shown in FIG. 3, and may be modified into various shapes for specific applications.

In the first embodiment of the present disclosure, it is preferable to mount the integrated MEMS chip 120 of the architecture shown in FIG. 3 by making the back-chamber 126 face the mounting surface of the lead frame 110.

After mounting the integrated MEMS chip 120 on the lead frame 110, the lead terminal and the ground terminal of the lead frame 110 are connected electrically to the integrated MEMS chip 120 by using the bonding wire 130. A molding compound is used to form the molded portion 140 for enclosing the lead frame 110, the integrated MEMS chip 120 and the bonding wire 130.

In this case, it is necessary to form the molded portion 140 so that the vibration unit 120a of the integrated MEMS chip 120 may be exposed. To this end, the molded portion 140 covers just the outer area of the vibration unit 120a to avoid hiding the diaphragm 123 or the backplate 122. By taking this measure, a sound diffusion chamber 160 communicating with the vibration unit 120a is formed in the center of the upper side of the molded portion 140.

Since the sound diffusion chamber 160 formed as such is wide in diameter, it is preferable to equip a protection cover on top thereof. In the first embodiment of the present disclosure, a shielding panel 150 formed with a sound hole 162 is equipped on the upper side of the molded portion 140 to cover the top of the sound diffusion chamber 160.

In particular, in the first embodiment of the present disclosure, a metallic shielding panel 150 is equipped on the upper side of the molded portion 140 to protect the integrated MEMS chip 120 from electromagnetic waves, and a shielding frame 112 is formed to be connected electrically to the shielding panel 150 on one side of the integrated MEMS chip 120. The shielding frame 112 is metallic, and may be formed by bending part of the lead frame 110 upward, or be installed as a different component from the lead frame 110.

It is preferable that the aforementioned shielding frame 112 is formed along all the outer edge of the integrated MEMS chip 120. While the shielding frame 112 is connected electrically to the ground electrode or (−) electrode of the integrated MEMS chip 120 through the bonding wire 130, it may be connected electrically to the ground terminal provided on the main substrate of an electronic device. By this connection, the shielding panel 150 and the shielding frame 112 protect the integrated MEMS chip 120 enclosed therein from external electromagnetic waves.

Meanwhile, it should be noted that the MEMS microphone package 100 in accordance with the first embodiment of the present disclosure may be modified into different shapes to be described herein below.

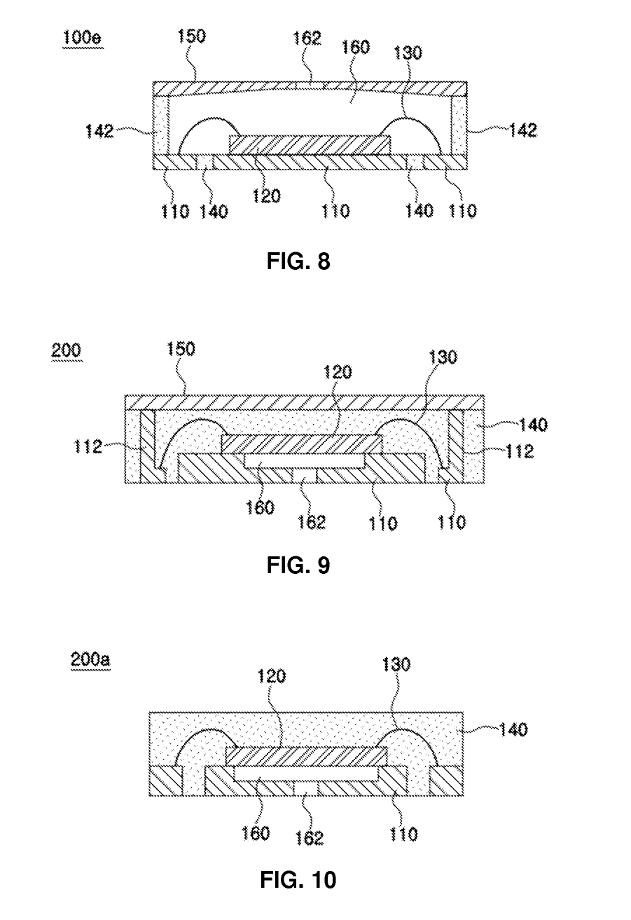

First, like the MEMS microphone package 100a shown in FIG. 4, the shielding panel 150 is coupled to the upper side of the molded portion 140 and the shielding frame connected to the shielding panel 150 may be omitted.

In addition, both the shielding panel 150 and the shielding frame 112 may be omitted like the MEMS microphone package 100b shown in FIG. 5. In this case, it is preferable to form a projected molding cover 144 on the inner wall of the molded portion 140 to cover the top of the sound diffusion chamber 160. It should also be noted that a sound hole 162 communicating with the sound diffusion chamber 160 is formed through the molding cover 144. In this case, the molding cover 144 may be independently manufactured and then coupled to the upper side of the molded portion 140.

In addition, like the MEMS microphone package 100c shown in FIG. 6, a lateral molding wall 142 may be formed along the upper outer edge of the lead frame 110, and the molding cover 144 formed with the sound hole 162 may be coupled to the upper end of the lateral molding wall 142, without forming the molded portion 140 enclosing the integrated MEMS chip 120 and the bonding wire 130.

By taking this measure, the space enclosed by the lateral molding wall 142 and the molding cover 144 is used as a sound diffusion chamber 160 communicating with the sound hole 162.

Meanwhile, the lateral molding wall 142 and the molding cover 144 may be manufactured independently with a molding compound and then used, or molded by using a molding compound in the packaging process steps. In the package 100c shown in FIG. 6, part of the lead frame 110 may also be enclosed and protected by the molded portion 140.

In addition, like the MEMS microphone package 100d shown in FIG. 7, the shielding panel 150 may be coupled to the molding cover 144 coupled to the upper end of the lateral molding wall 142. As shown in FIG. 7, the shielding panel 150 may be buried in the molding cover 144, or coupled to the outer side or inner side of the molding cover 144. In addition, although not shown in FIG. 7, a shielding panel may be coupled to or buried in the lateral molding wall 142.

In addition, like the MEMS microphone package 100e shown in FIG. 8, a metallic shielding panel 150 with the sound hole 162 may be coupled on the upper end of the lateral molding wall 142.

In the MEMS microphone packages 100, 100a, 100b, 100c, 100d and 100e in accordance with the first embodiment of the present disclosure described above, the sound hole 162 for introducing sound waves is formed on the opposite side of the lead frame 110 coupled to the main substrate of an electronic device.

However, in some cases, it is necessary to form the sound hole 162 through the lead frame 110 depending on the path of introduced sound, and a MEMS microphone package with such a configuration is described hereinafter.

### Second Embodiment

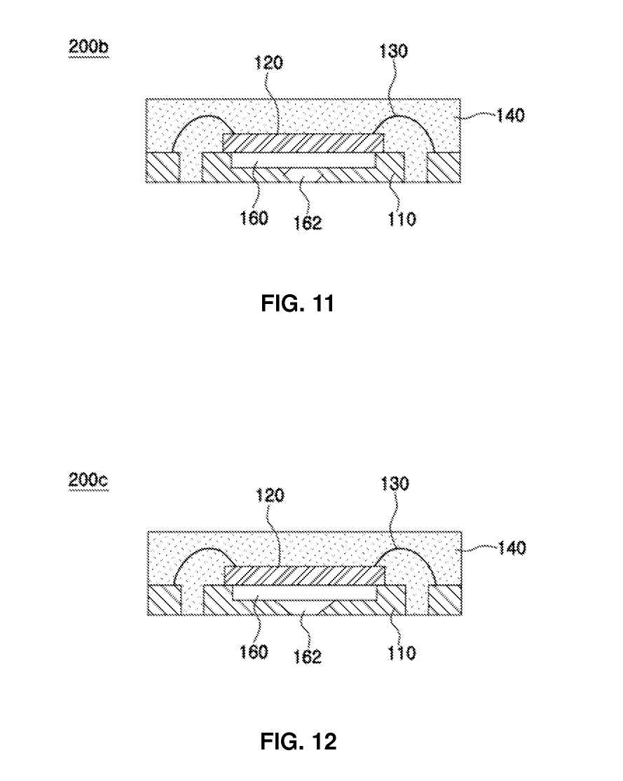

The MEMS microphone package 200 in accordance with the second embodiment of the present disclosure includes a metallic lead frame 110, an integrated MEMS chip 120 located on top of the lead frame 110, a bonding wire 130 for connecting the lead frame 110 electrically to the integrated MEMS chip 120, a molded portion 140 for enclosing the lead frame 110, the integrated MEMS chip 120 and the bonding wire 130, and a shielding panel 150 coupled to the upper side of the molded portion 140 as shown in the cross sectional view of FIG. 9.

Since the configuration of the integrated MEMS chip 120 is the same as the configuration of the first embodiment, it is not further described.

In the second embodiment of the present disclosure, a sound diffusion chamber 160 is formed between the lead frame 110 and the integrated MEMS chip 120, and communicates with the outside through the sound hole 162 formed through the lead frame 110. If the sound hole 162 is formed through the lead frame 110, it is necessary to form a hole corresponding to the sound hole 162 on the main substrate of an electronic device where the package 200 is mounted in order to introduce sound waves.

A concave portion may be formed on the upper side of the lead frame 110 to function as a sound diffusion chamber 160. In addition, the lower outer area of the integrated MEMS chip 120 is placed on the lead frame 110 enclosing the concave portion. It is preferable to mount the integrated MEMS chip 120 of the architecture of FIG. 3 on the lead frame 110 so that the back-chamber 126 may be inverted to face upward.

After mounting the integrated MEMS chip 120 on the lead frame 110, the terminal of the lead frame 110 is connected electrically to the integrated MEMS chip 120 by using the bonding wire 130, and the molded portion 140 may be formed to enclose all of the lead frame 110, the integrated MEMS chip 120 and the bonding wire 130 by using a molding compound.

In this case, since the back-chamber 126 of the integrated MEMS chip 120 is open upward, it is preferable to form the molded portion 140 while the back-chamber 126 is shielded with a special cover member (not shown) to avoid filling the back-chamber 126 with the molded portion 140.

Even in the second embodiment of the present disclosure, a metallic shielding panel 150 may be mounted on the upper side of the molded portion 140 to protect the integrated MEMS chip 120 from electromagnetic waves, and a shielding frame 112 connected electrically to the shielding panel 150 may be formed at one side of the integrated MEMS chip 120. The shielding frame 112 may be made by bending part of the lead frame 110 upward, or be a separate metallic frame.

Meanwhile, the MEMS microphone package 200 in accordance with the second embodiment of the present disclosure may be modified into various types to be described herein below.

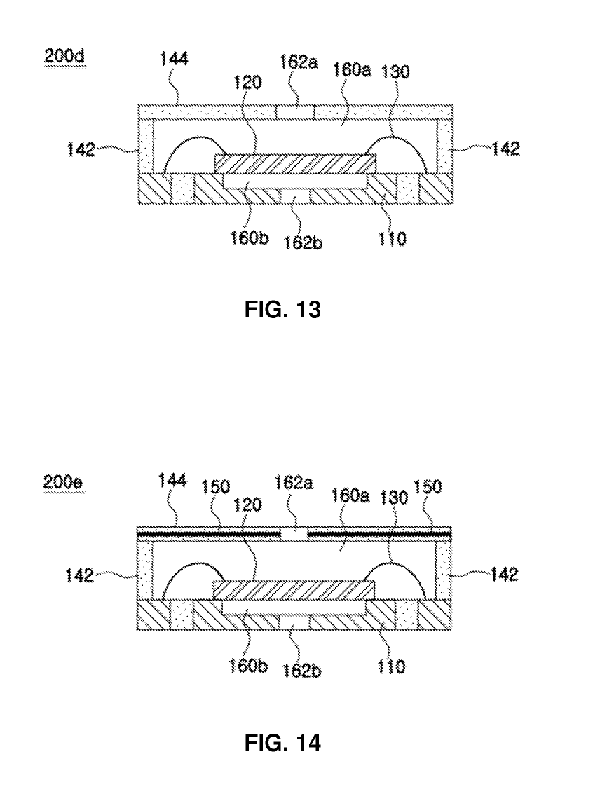

First, like the MEMS microphone package 200a shown in FIG. 10, the shielding panel formed on the upper side of the molded portion 140 and the shielding frame connected to the lead frame 110 may be omitted.

In addition, like the MEMS microphone package 200b shown in FIG. 11, the sound hole 162 of the lead frame 110 may be formed to have a special shape. That is, the sound hole 162 may be formed to have a shape of which the middle diameter is the greatest and the diameter is smaller as it goes toward the outer side and the inner side.

In addition, like the MEMS microphone package 200c shown in FIG. 12, the sound hole 162 may be formed to have a shape of which the diameter is greater as it goes toward the inner side. Although not shown in FIG. 12, the sound hole 162 may be formed to have a shape of which the diameter is smaller as it goes toward the inner side.

As described above, various shapes of the sound hole 162 contribute to enabling sensitivity to be controlled in conformity with sound features.

Meanwhile, in the MEMS microphone packages 200, 200a, 200b and 200c shown in FIGS. 9 to 12, the molded portion 140 encloses all of the integrated MEMS chip 120, the bonding wire 130 and the lead frame 110, but is not limited to those configurations.

That is, like the MEMS microphone package 200d shown in FIG. 13, a lateral molding wall 142 may be formed along the upper outer edge of the lead frame 110 and a molding cover 144 formed with a sound hole 162a may be coupled to the upper end of the lateral molding wall 142 without forming a molded portion enclosing the integrated MEMS chip 120 and the bonding wire 130.

By taking this measure, the space enclosed by the lateral molding wall 142 and the molding cover 144 may be used as a first sound diffusion chamber 160a communicating with the sound hole 162a, and the space formed between the lead frame 110 and the integrated MEMS chip 120 may be used as a second sound diffusion chamber 160b communicating with the sound hole 162b.

As described above, the first and the second sound diffusion chambers 160a and 160b formed above and below the integrated MEMS chip 120 enable sensitivity to be controlled in conformity with the path of introduced sound or features of sound.

In FIG. 13, the lateral molding wall 142 and the molding cover 144 may also be independently manufactured by using a molding compound, or may be molded by using a molding compound in the packaging process steps. Part of the lead frame 110 may be protected by enclosing it with the molded portion 140.

In addition, like the MEMS microphone package 200e shown in FIG. 14, the shielding panel 150 may be coupled to the molding cover 144 coupled to the upper end of the lateral molding wall 142. As shown in FIG. 14, the shielding panel 150 may be buried in the molding cover 144, or coupled to the outer side or inner side of the molding cover 144. In addition, although not shown in FIG. 14, a shielding panel may be coupled to or buried in the lateral molding wall 142.

Although the embodiments of the present disclosure are described above, the present disclosure is not limited to the aforementioned embodiments and may be modified or changed into various types. It should be noted that modifications and changes are covered by the present disclosure if they include the technical idea of the present disclosure disclosed in the following claims.

### DESCRIPTION OF NUMERALS

| | |
|---|---|
| 100: MEMS microphone package | 110: lead frame |
| 112: shielding frame | 120: integrated MEMS chip |
| 120a: vibration unit | 120b: signal processing unit |
| 121: silicon substrate | 122: backplate |
| 123: diaphragm | 125: air gap |
| 126: back-chamber | 130: bonding wire |
| 140: molded portion | 142: lateral molding wall |
| 144: molding cover | 150: shielding panel |
| 160: sound diffusion chamber | 162: sound hole |

What is claimed is:

1. An MEMS microphone package, the microphone package comprising:
a lead frame;
an integrated MEMS chip mounted on the lead frame, having a vibration unit comprising a diaphragm and a backplate spaced each other with an air gap between them and a signal processing unit for amplifying electric signals generated in the vibration unit, the vibrating unit and the signal processing unit being formed on a single silicon substrate, the vibrating unit being formed on a first area of the silicon substrate through MEMS process and the signal processing unit being formed on a second area located in the lateral direction of the first area of the silicon substrate; and
an electric connection means for connecting the lead frame to the integrated MEMS chip,
wherein the second area of the integrated MEMS chip encloses the first area.

2. An MEMS microphone package, the microphone package comprising:
a lead frame;
an integrated MEMS chip mounted on the lead frame, having a vibration unit comprising a diaphragm and a backplate spaced each other with an air gap between them and a signal processing unit for amplifying electric signals generated in the vibration unit, the vibrating unit and the signal processing unit being formed on a single silicon substrate, the vibrating unit being formed on a first area of the silicon substrate through MEMS process and the signal processing unit being formed on a second area located in the lateral direction of the first area of the silicon substrate;
an electric connection means for connecting the lead frame to the integrated MEMS chip; and
a molded portion for enclosing the electric connection means, the integrated MEMS chip and the lead frame,
wherein the molded portion encloses the outer area of a sound diffusion chamber formed on one side of the integrated MEMS chip;
a metallic shielding panel covering the top of the sound diffusion chamber is coupled to the upper side of the molded portion; and
the shielding panel is formed with a sound hole communicating with the sound diffusion chamber.

3. The microphone package of claim 2, wherein the lead frame comprises a shielding frame connected to the shielding panel through the molded portion.

4. An MEMS microphone package, the microphone package comprising:
a lead frame;
an integrated MEMS chip mounted on the lead frame, having a vibration unit comprising a diaphragm and a backplate spaced each other with an air gap between them and a signal processing unit for amplifying electric signals generated in the vibration unit, the vibrating unit and the signal processing unit being formed on a single silicon substrate, the vibrating unit being formed on a first area of the silicon substrate through MEMS process and the signal processing unit being formed on a second area located in the lateral direction of the first area of the silicon substrate;
an electric connection means for connecting the lead frame to the integrated MEMS chip; and
a molded portion for enclosing the electric connection means, the integrated MEMS chip and the lead frame,
wherein a sound diffusion chamber is formed between the lead frame and the integrated MEMS chip;
a sound hole communicating with the sound diffusion chamber is formed through the lead frame; and
a metallic shielding panel is coupled to the upper side of the molded portion.

5. The microphone package of claim 4, wherein the lead frame comprises a shielding frame connected to the shielding panel through the molded portion.

6. An MEMS microphone package, the microphone package comprising:
a lead frame;
an integrated MEMS chip mounted on the lead frame, having a vibration unit comprising a diaphragm and a backplate spaced each other with an air gap between them and a signal processing unit for amplifying electric signals generated in the vibration unit, the vibrating unit and the signal processing unit being formed on a single silicon substrate, the vibrating unit being formed on a first area of the silicon substrate through MEMS process and the signal processing unit being formed on a second area located in the lateral direction of the first area of the silicon substrate;
an electric connection means for connecting the lead frame to the integrated MEMS chip;
a lateral molding wall formed along the outer area of the lead frame; and
a molding cover coupled to the upper end of the lateral molding wall and formed with a sound hole,
wherein the space enclosed by the lateral molding wall and the molding cover is provided as a sound diffusion chamber; and
a metallic shielding panel is coupled to at least one of the lateral molding wall and the molding cover.

7. An MEMS microphone package, the microphone package comprising:
a lead frame;
an integrated MEMS chip mounted on the lead frame, having a vibration unit comprising a diaphragm and a backplate spaced each other with an air gap between them and a signal processing unit for amplifying electric signals generated in the vibration unit, the vibrating unit and the signal processing unit being formed on a single silicon substrate, the vibrating unit being formed on a first area of the silicon substrate through MEMS process and the signal processing unit being formed on a second area located in the lateral direction of the first area of the silicon substrate;
an electric connection means for connecting the lead frame to the integrated MEMS chip;
a lateral molding wall formed along the outer area of the lead frame; and
a metallic shielding panel coupled to the upper end of the lateral molding wall and formed with a sound hole,
wherein the space enclosed by the lateral molding wall and the shielding panel is provided as a sound diffusion chamber.

8. The microphone package of claim 6, wherein a second sound diffusion chamber is formed between the lead frame and the integrated MEMS chip; and the lead frame is formed with a sound hole communicating with the second sound diffusion chamber.

9. The microphone package of claim 7, wherein a second sound diffusion chamber is formed between the lead frame and the integrated MEMS chip; and the lead frame is formed with a sound hole communicating with the second sound diffusion chamber.
